(19) United States
(12) Patent Application Publication
(10) Pub. No.: US 2009/0153171 A1
(43) Pub. Date: Jun. 18, 2009

(54) Apparatus for testing objects under controlled conditions

(76) Inventors: Sang-Sik Lee, Suwon-si (KR); Yun-Ha Park, Suwon-si (KR); Sung-Min Sim, Seongnam-si (KR); Myoung-Sub Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/314,360

(22) Filed: Dec. 9, 2008

(30) Foreign Application Priority Data
Dec. 13, 2007 (KR) 2007-129598

(51) Int. Cl. G01R 31/28

(52) U.S. Cl. 324/760

(57) ABSTRACT

An apparatus for testing objects includes a test board having electrical connection areas to connect to the objects, a chamber fixture located on the test board to form test chambers that are configured to individually receive the objects, a thermoelectric element provided to each test chamber to adjust the temperature of the object, and a temperature controller for individually controlling operations of the thermoelectric elements.

### BACKGROUND

1. Technical Field

Embodiments relate to an apparatus for testing objects.

2. Description of the Related Art

Generally, various semiconductor fabrication processes may be performed on a semiconductor substrate to form a plurality of semiconductor chips. In order to mount the semiconductor chips on a printed circuit board (PCB), a packaging process may be performed on the semiconductor chips to form semiconductor packages.

Electrical characteristics of the semiconductor packages manufactured by the above-mentioned processes may be tested. A conventional apparatus for testing the semiconductor package may include a test board electrically connected to the semiconductor packages, test sockets configured to hold the semiconductor packages on the test board, a chamber fixture mounted on the test board to form a single test chamber that may be configured to receive the test sockets, and a temperature controller for controlling an inner temperature of the test chamber.

The conventional temperature controller may provide air into the test chamber to control the inner temperature of the test chamber. That is, a testing apparatus using the conventional temperature controller may be an indirect control type where temperatures of all of the test sockets in the single test chamber may be controlled using the air. This may cause a wide temperature deviation between the semiconductor packages in the test chamber. The temperature deviation may cause low reliability of temperature test results with respect to the semiconductor packages. Additionally, the semiconductor packages may not be tested at different temperatures at the same time using the conventional apparatus. Further, because the conventional apparatus may include a test chamber having a very large inner space, a very long time may be required to set the inner temperature of the test chamber.

Moreover, when the semiconductor package is tested at a relatively low temperature, a heat exchange between a cold portion of the test socket and hot air in the test chamber may produce frost and/or ice on the test socket.

### SUMMARY

Embodiments are therefore directed to an apparatus for testing an object under controlled conditions and associated methods, which substantially overcome one or more of the problems due to the limitations and disadvantages of the related art.

It is therefore a feature of an embodiment to provide an apparatus for testing objects that ensures uniform or controlled deviation in temperatures, and high reliability of test results.

It is therefore another feature of an embodiment to provide an apparatus for testing objects that does not produce frost or ice during testing of the objects.

It is therefore another feature of an embodiment to provide an apparatus for testing objects that ensures an inner temperature of the test chamber is set in a short amount of time.

At least one of the above and other features and advantages may be realized by providing an apparatus for testing objects, including a test board having electrical connection areas to connect to the objects, a chamber fixture located on the test board to form a plurality of test chambers that are configured to individually receive the objects, a thermoelectric element in each test chamber to adjust the temperature of the objects, and a temperature controller for individually controlling operations of respective thermoelectric elements.

The apparatus may include a cooling line connected to the test chambers to supply a coolant for heating and/or cooling the test chambers. The cooling line may be located in a ceiling of the test chambers.

The apparatus may include an air line connected to the test chambers to supply air into the test chambers. The air line may be located in a sidewall of the test chambers.

The apparatus may include a heat transferring member arranged between the electrical connection area and the thermoelectric element of each test chamber to transfer a heat generated from the objects to the thermoelectric element, and a heat spreader in each test chamber making contact with an upper surface of the thermoelectric element to dissipate heat from the thermoelectric element.

The apparatus may include a knob threadedly attached to a ceiling of each test chamber to adjust a gap between the heat transferring member and the test board. The knob may be arranged on an upper surface of the ceiling of each test chamber and movably inserted into the heat spreader to contact an upper surface of the heat transferring member.

The heat transferring member may include copper (Cu). The heat transferring member may include a gold (Au) layer on a surface of the heat transferring member.

The heat spreader may have a cooling passageway through which a coolant supplied from the temperature controller can flow.

The thermoelectric element may include a first and a second heat-emitting plate, a heat-absorbing plate electrically connected to the first and second heat-emitting plates, and N-type and P-type semiconductor devices interposed between the heat-absorbing plate and the first and second heat-emitting plates.

The objects may include semiconductor packages.

At least one of the above and other features and advantages may also be realized by providing an apparatus for testing semiconductor packages, including a test board having electrical connection areas for connecting to semiconductor packages, a chamber fixture located on the test board to form a plurality of test chambers that are configured to individually receive semiconductor packages, a thermoelectric element in each test chamber to cool or heat the semiconductor package, a heat transferring member arranged between the test board and the thermoelectric element to transfer a heat generated from the semiconductor package to the thermoelectric element, a heat spreader in each test chamber and contacting an upper surface of the thermoelectric element to dissipate the heat in the thermoelectric element, a temperature controller for individually controlling operations of the thermoelectric elements, a cooling line connected to the test chambers to supply a coolant to the test chambers, and an air line connected to the test chambers to supply air to the test chambers.

The cooling line may be in a ceiling of each test chamber, and the cooling line may be in fluidic contact with a cooling passageway in the heat spreader.

The apparatus may include a knob threadedly connected to a ceiling of each test chamber to adjust a gap between the heat transferring member and the test board. The knob may be arranged on an upper surface of the ceiling of each test chamber and movably inserted into the heat spreader to contact an upper surface of the heat transferring member.

### BRIEF DESCRIPTION OF THE DRAWINGS

The above and other features and advantages of the embodiments will become more apparent to those of ordinary skill in the art by describing in detail exemplary embodiments thereof with reference to the attached drawings, in which:

FIG. 1 illustrates a perspective view of an apparatus for testing objects according to an exemplary embodiment;

FIG. 2 illustrates an upper perspective view of a chamber fixture of the apparatus illustrated in FIG. 1;

FIG. 3 illustrates a lower perspective view of the chamber fixture of the apparatus illustrated in FIG. 1;

FIG. 4 illustrates a cross-sectional view of an inner structure of a single test chamber in the apparatus illustrated in FIG. 1;

FIG. 5 illustrates an upper perspective view of the test chamber illustrated in FIG. 4;

FIG. 6 illustrates a lower perspective view of the test chamber illustrated in FIG. 4; and

FIG. 7 illustrates a cross-sectional view of a thermoelectric element in the test chamber illustrated in FIG. 4.

### DETAILED DESCRIPTION OF THE EMBODIMENTS

Korean Patent Application No. 2007-129598, filed on Dec. 13, 2007, in the Korean Intellectual Property Office, and entitled: “Apparatus for Testing an Object,” is incorporated by reference herein in its entirety.

Exemplary embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not. The term “and/or” includes any and all combinations of one or more of the associated listed items.

As used herein, the expression “or” is not an “exclusive or” unless it is used in conjunction with the term “either.” For example, the expression “A, B, or C” includes A alone; B alone; C alone; both A and B together; both A and C together; both B and C together; and all three of A, B, and C together, whereas the expression “either A, B, or C” means one of A alone, B alone, and C alone, and does not mean any of both A and B together; both A and C together; both B and C together; and all three of A, B, and C together.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout.

It will be understood that, although the terms first, second, third etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

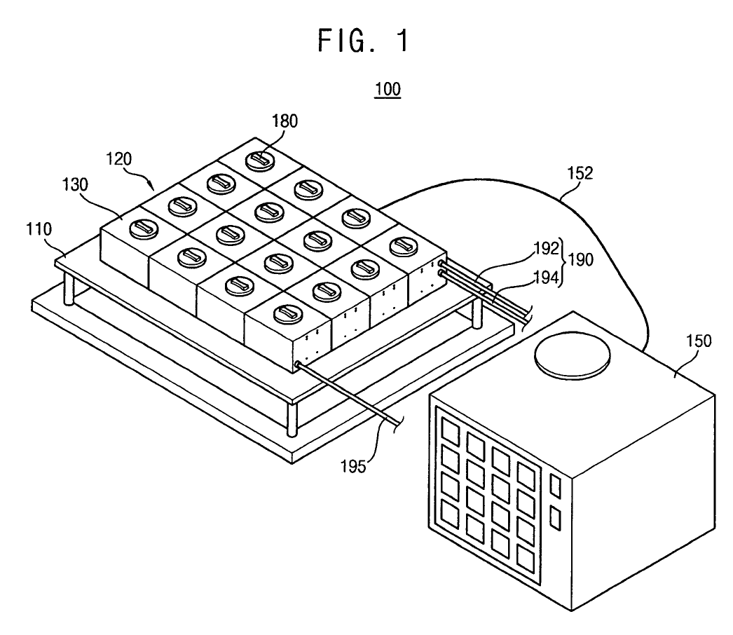

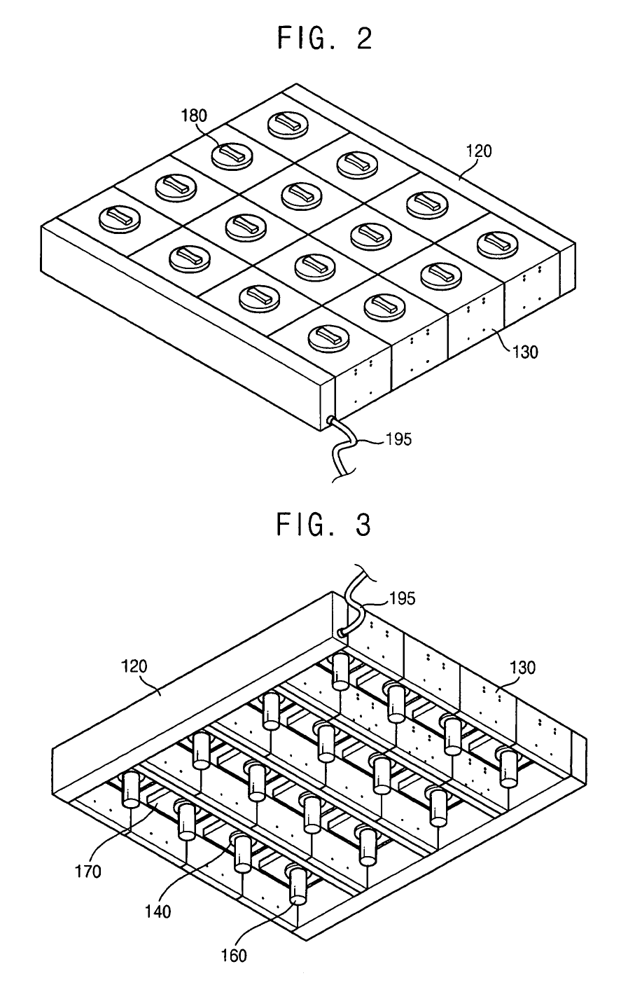

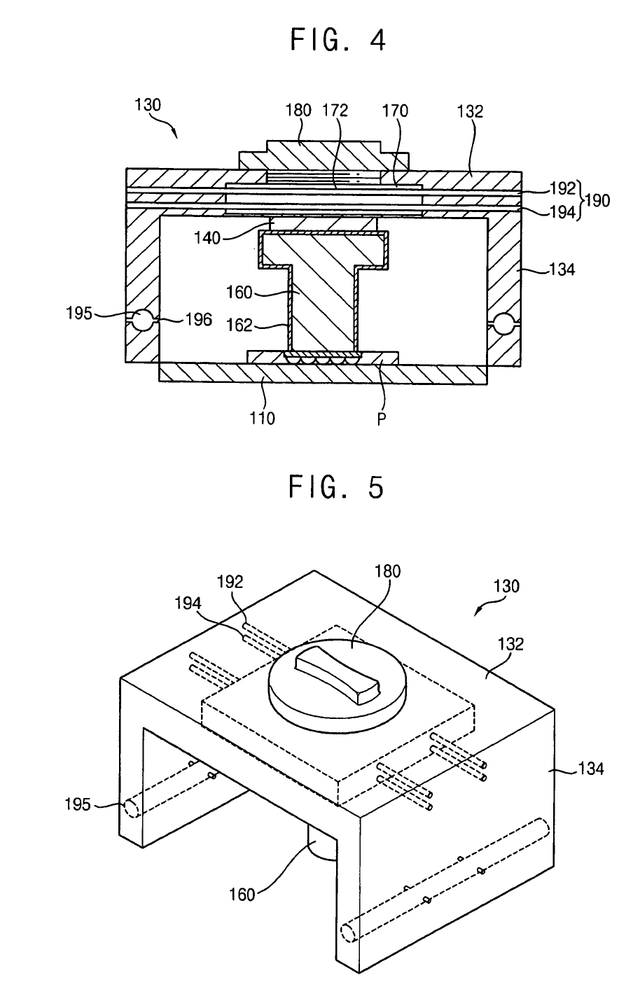

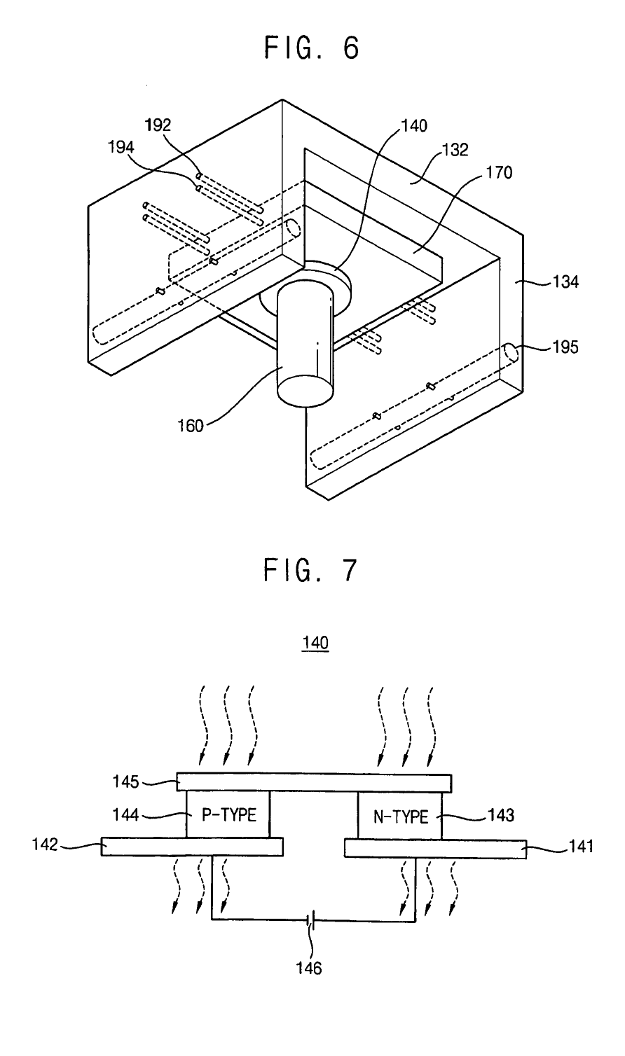

Referring to FIGS. 1 to 7, an embodiment is directed to an apparatus 100 for testing electrical characteristics of an object. In an exemplary embodiment, the object may be a semiconductor package P (see FIG. 4). Each semiconductor package P may include a plurality of solder balls as external terminals. The apparatus 100 may include a test board 110, a chamber fixture 120, a thermoelectric element 140 (see FIG. 3), a temperature controller 150, a heat transferring member 160 (see FIG. 3), a heat spreader 170 (see FIG. 3), a knob 180, a cooling line 190, and an air line 195.

The semiconductor package P may be placed on the test board 110 and may be electrically coupled to the test board 110. The test board 110 may have a plurality of test patterns (not shown) to make electrical contact with the solder balls of the semiconductor packages P.

The chamber fixture 120 may be mounted on the test board 110. The chamber fixture 120 may include a plurality of test chambers 130 configured to isolate the test patterns from one another

Referring to FIG. 5, in an exemplary embodiment, a plurality of sidewalls 134 may downwardly extend from a ceiling 132 of the chamber fixture 120 to form isolated test chambers 130. Each of the test chambers 130 may include the ceiling 132 and four sidewalls 134 downwardly extending from the ceiling 132. A bottom surface of the each of the test chambers 130 may correspond to the top surface of the test board 110. The test chambers 130 may be arranged at substantially the same interval along lengthwise and breadthwise directions. Adjacent test chambers 130 may commonly share a single sidewall 134. As a result, each of the test chambers 130 may have a rectangular parallelepiped inner space.

Referring to FIG. 4, the thermoelectric elements 140 may be arranged in the test chambers 130. The thermoelectric element 140 may serve to vary the temperature during testing of the semiconductor package P. In an exemplary embodiment, the thermoelectric elements 140 may be located adjacent to the ceiling of each of the test chambers 130. The thermoelectric elements 140 may be adjustable so as to move vertically in the test chambers 130. The thermoelectric element 140 may be capable of emitting heat and absorbing heat by a current provided to the thermoelectric element 140 in accordance with the Peltier effect. Thus, the thermoelectric elements 140 may vary the temperature upward and/or downward for testing of the semiconductor packages P.

Referring to FIG. 7, the thermoelectric element 140 may include a first and second heat-emitting plate 141 and 142, a heat-absorbing plate 145 opposite to the first and second heat-emitting plates 141 and 142, and N type and P type semiconductor devices 143 and 144 interposed between the heat-absorbing plate 145 and the first and second heat-emitting plates 141 and 142. A power supply 146 may be electrically connected to the first and second heat-emitting plates 141 and 142.

A current may be provided to the first heat-emitting plate 141 from the power supply 146. The current may flow to the second heat-emitting plate 142 through the N type semiconductor device 143, the heat-absorbing plate 145, and the P type semiconductor device 144. Thus, the first and second heat-emitting plates 141 and 142 may emit heat. The heat-absorbing plate 145 may absorb heat. In another implementation, a current may be provided to the second heat-emitting plate 142 from the power supply 146. The current may flow to the first heat-emitting plate 141 through the P type semiconductor device 144, the heat-absorbing plate 145, and the N type semiconductor device 143. Thus, the first and second heat-emitting plates 141 and 142 may absorb heat. The heat-absorbing plate 145 may emit heat. This may be due to the well-known Peltier effect.

The Peltier effect may be explained using the free electron gas model, similar to an ideal gas cooled by a constant entropy expansion. When an electron moves from a semiconductor having a high electron concentration to a semiconductor having a low electron concentration, an electron gas may expand and do work with respect to a potential barrier between two plates having a substantially similar chemical potential, thereby electrically cooling an object.

The temperature controller 150 may selectively provide a current to the thermoelectric elements 140 through a cable 152. Because the thermoelectric elements 140 may be arranged in the isolated test chambers 130, inner temperatures of the test chambers 130 may be individually controlled using the temperature controller 150.

The heat transferring members 160 may be arranged between the semiconductor packages P on the test board 1 10 and the thermoelectric elements 140. The heat transferring member 160 may have a lower surface making contact with the semiconductor package P and an upper surface making contact with the thermoelectric element 140. The heat transferring member 160 may apply pressure to an upper surface of the semiconductor package P to ensure a contact between the solder balls of the semiconductor package P and the test pattern of the test board 110. The heat transferring member 160 and the thermoelectric element 140 may be thermally connected to each other. Heat generated from the thermoelectric elements 140 may be directly transferred to the semiconductor package P through the heat transferring member 160. In an exemplary embodiment, the heat transferring member 160 may include copper (Cu), which has a high thermal conductivity. Additionally, in order to increase the thermal conductivity of the heat transferring member 160, a gold (Au) layer 162, which has a thermal conductivity higher than that of copper, may be coated on the heat transferring member 160.

The heat spreaders 170 may be built in the ceiling of the test chambers 130. The heat spreader 170 may make contact with a surface of the thermoelectric element 140. Heat, which may be generated by the semiconductor package P and the thermoelectric element 140, may be rapidly dissipated through the heat spreader 170. Additionally, because a radiation effect may be proportional to the surface area of the heat spreader 170, the heat spreader 170 may have a plurality of protrusions (not shown) to enlarge the surface area of the heat spreader 170.

The knobs 180 may be threadedly connected to an upper surface of the ceiling of the test chamber 130. The knob 180 may be movably inserted into the heat spreader 170 and make contact with a surface of the thermoelectric element 140. The thermoelectric element 140 and the heat transferring member 160 may ascend or descend together in accordance with rotational directions of the knob 180. Because semiconductor packages P may have different thicknesses, a gap between the heat transferring member 160 and the test board 110 may be adjusted using the knob 180 to receive the semiconductor packages P.

In order to supplement the cooling and heating operation of the thermoelectric elements 140, a cooling line 190 may be connected to the test chambers 130. The cooling line 190 may have an inlet line 192 in which a coolant may flow, and an outlet line 194 out which the coolant may flow. The coolant flowing in the test chambers 130 through the inlet line 192 may heat and/or cool the first and the second heat-emitting plates 141 and 142 and the heat-absorbing plate 145 of the thermoelectric elements 140 to facilitate operation of the thermoelectric elements 140. After heating/cooling, the coolant may flow out through the outlet line 194. The temperature controller 150 may control the temperature and flux, i.e., flow rate, of the coolant. In an exemplary embodiment, the cooling line 190 may be built in the ceiling of the test chambers 130 in a horizontal direction.

In order to increase the heat dissipation of the heat spreader 170, the heat spreader 170 may have a cooling passageway 172 in fluidic contact with the cooling line 190. The cooling passageway 172 may be formed in the heat spreader 170 in a first horizontal direction. As a result, the coolant flowing through the cooling line 190 may be directly heat-exchanged with the heat spreader, so that the heat dissipation of the heat spreader 170 may be significantly improved.

The air line 195 may be connected to the test chambers 130. Air vented to the test chamber 130 through the air line 195 and vents 196 may remove frost and/or ice generated on the semiconductor packages during a cooling test. In an exemplary embodiment, the air line 195 may be built in the sidewalls 134 of the test chambers 130 in a second horizontal direction substantially perpendicular to the first horizontal direction. The air line 195 may be in fluidic contact with the test chambers 130. The temperature controller 150 may control the temperature and flux of the air in the air line 195.

In an exemplary embodiment, the object being tested may include a semiconductor package. However, the object being tested is not restricted to only semiconductor packages. Electrical characteristics of any suitable electronic elements having external terminals may be tested using the apparatus of an exemplary embodiment.

According to an exemplary embodiment, the inner temperatures of the test chambers may be controlled individually and directly. Thus, a temperature deviation between the semiconductor packages may be decreased. Individual semiconductor packages may also be tested at different temperatures from one another.

Furthermore, the radiation effect of the heat spreader may be remarkably improved using the coolant and the cooling line. Because air may be supplied to the separate test chambers, frost and/or ice may be avoided on the semiconductor packages in the test chambers.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An apparatus for testing objects, comprising:
a test board having electrical connection areas to connect to the objects;
a chamber fixture located on the test board to form a plurality of test chambers that are configured to individually receive the objects;
a thermoelectric element in each test chamber to adjust the temperature of the objects; and
a temperature controller for individually controlling operations of the respective thermoelectric elements.

2. The apparatus as claimed in claim 1, further comprising a cooling line connected to the test chambers to supply a coolant for heating and/or cooling the test chambers.

3. The apparatus as claimed in claim 2, wherein the cooling line is located in a ceiling of the test chambers.

4. The apparatus as claimed in claim 1, further comprising an air line connected to the test chambers to supply air into the test chambers.

5. The apparatus as claimed in claim 4, wherein the air line is located in a sidewall of the test chambers.

6. The apparatus as claimed in claim 1, further comprising:
a heat transferring member arranged between the electrical connection area and the thermoelectric element of each test chamber to transfer a heat generated from the objects to the thermoelectric element; and
a heat spreader in each test chamber making contact with an upper surface of the thermoelectric element to dissipate heat from the thermoelectric element.

7. The apparatus as claimed in claim 6, further comprising a knob threadedly attached to a ceiling of each test chamber to adjust a gap between the heat transferring member and the test board.

8. The apparatus as claimed in claim 7, wherein the knob is arranged on an upper surface of the ceiling of each test chamber and movably inserted into the heat spreader to contact an upper surface of the heat transferring member.

9. The apparatus as claimed in claim 6, wherein the heat transferring member includes copper (Cu).

10. The apparatus as claimed in claim 9, wherein the heat transferring member includes a gold (Au) layer on a surface of the heat transferring member.

11. The apparatus as claimed in claim 6, wherein the heat spreader has a cooling passageway through which a coolant supplied from the temperature controller can flow.

12. The apparatus as claimed in claim 1, wherein the thermoelectric element includes:
a first and a second heat-emitting plate;
a heat-absorbing plate electrically connected to the first and second heat-emitting plates; and
N-type and P-type semiconductor devices interposed between the heat-absorbing plate and the first and second heat-emitting plates.

13. The apparatus as claimed in claim 1, wherein the objects include semiconductor packages.

14. An apparatus for testing semiconductor packages, comprising:
a test board having electrical connection areas for connecting to semiconductor packages;
a chamber fixture located on the test board to form a plurality of test chambers that are configured to individually receive semiconductor packages;
a thermoelectric element in each test chamber to cool or heat the semiconductor package;
a heat transferring member arranged between the test board and the thermoelectric element to transfer a heat generated from the semiconductor package to the thermoelectric element;
a heat spreader in each test chamber and contacting an upper surface of the thermoelectric element to dissipate the heat in the thermoelectric element;
a temperature controller for individually controlling operations of the thermoelectric elements;
a cooling line connected to the test chambers to supply a coolant to the test chambers; and
an air line connected to the test chambers to supply air to the test chambers.

15. The apparatus as claimed in claim 14, wherein the cooling line is in a ceiling of the test chambers, and the cooling line is in fluidic contact with a cooling passageway in the heat spreader.

16. The apparatus as claimed in claim 15, further comprising a knob threadedly connected to a ceiling of each test chamber to adjust a gap between the heat transferring member and the test board.

17. The apparatus as claimed in claim 16, wherein the knob is arranged on an upper surface of the ceiling of each test chamber and movably inserted into the heat spreader to contact an upper surface of the heat transferring member.
